(19) United States
(12) Patent Application Publication
(10) Pub. No.: US 2018/0166105 A1
(43) Pub. Date: Jun. 14, 2018

(54) MEMORY MODULE INCLUDING MEMORY GROUP

(71) Applicant: Samsung Electronics Co., Ltd., Suwon-si (KR)

(72) Inventors: Il-han CHOI, Hwaseong-si (KR); Jae-jun Lee, Seongnam-si (KR); Dong-yeop Kim, Hwaseong-si (KR); Kyu-dong Lee, Seoul (KR); Jeong-hyeon Cho, Hwaseong-si (KR)

(73) Assignee: Samsung Electronics Co., Ltd., Suwon-si (KR)

(21) Appl. No.: 15/688,013

(22) Filed: Aug. 28, 2017

(30) Foreign Application Priority Data
Dec. 9, 2016 (KR) 10-2016-0168004

(51) Int. Cl. G11C 5/02

(52) U.S. Cl. CPC G11C 5/025; G11C 2207/229; G11C 2207/2281

(57) ABSTRACT

A memory module may include a first memory group and a second memory group; and a first clock signal line and a second clock signal line via which the first clock signal and the second clock signal propagate from the buffer chip to the first memory group and the second memory group, respectively, wherein distances that the first clock signals propagate from a buffer chip to a plurality of memory chips of the first memory group via the first clock signal line are identical to one another and are referred to as a first distance, and distances that the second clock signals propagate from the buffer chip to a plurality of memory chips of the second memory group via the second clock signal line are identical to one another and are referred to as a second distance.

### CROSS-REFERENCE TO RELATED APPLICATION

This application claims the benefit of Korean Patent Application No. 10-2016-0168004, filed on Dec. 9, 2016, in the Korean Intellectual Property Office, the disclosure of which is incorporated herein in its entirety by reference.

### BACKGROUND

Inventive concepts relate to a memory module, and more particularly, to a memory module including a plurality of memory chips that are classified into groups, such that memory chips in a same memory group receive the same clock signals.

A computer may utilize various types of memories to store data. Respective memories may be mounted directly on a mainboard in a computer. However, in order to resolve problems regarding size and complexity of a computer, a memory module for mounting a plurality of memories thereon may be used. However, as more memory modules are mounted onto connectors of a mainboard, factors including impedance discontinuity due to the connectors may deteriorate integrity of signals and may interfere with a high-speed operation. Therefore, overcoming these concerns may be necessary or desirable.

### SUMMARY

Inventive concepts provides a memory module for ensuring the integrity of controls signal and clock signals transmitted to a semiconductor memory device and including signal lines, through which the control signals and the clock signals propagate, efficiently arranged for easy fabrication of the memory module.

In one example embodiment of inventive concepts, there is provided a memory module comprising a first memory group and a second memory group, each comprising a plurality of memory chips; a buffer chip configured to output a control signal, first clock signals, and second clock signals; a control signal line connected to the buffer chip, at least some memory chips of the plurality of chips of the first memory group, and at least some memory chips of the plurality of chips of the second memory group; a first clock signal line through which the plurality of first clock signals are configured to propagate from the buffer chip to the at least some memory chips of the plurality of memory chips of the first memory group; and a second clock signal line through which second clock signals are configured to propagate from the buffer chip to the at least some memory chips of the plurality of memory chips of the second memory group. At least some distances that the first clock signals propagate from the buffer chip to the at least some memory chips of the plurality of memory chips of the first memory group through the first clock signal line are identical to one another, and at least some distances that the second clock signals propagate from the buffer chip to the at least some memory chips of the plurality of memory chips of the second memory group through the second clock signal line are identical to one another.

In one example embodiment of inventive concepts, there is provided a memory module comprising a first memory group and a second memory group, each comprising a plurality of memory chips; a buffer chip configured to output control signals, first clock signals, and second clock signals; a first control signal line connected to the buffer chip, at least some memory chips of the plurality of memory chips of the first memory group, and at least some memory chips of the plurality of memory chips of the second memory group and configured to transmit the control signal from the buffer chip to the first and second memory groups, a first clock signal line configured to transmit the first clock signals to the plurality of memory chips of the first memory group; and a second clock signal line configured to transmit the second clock signals to the plurality of memory chips of the second memory group. Distances from the buffer chip to the at least some memory chips of the plurality of memory chips of the first memory group is different from distances from the buffer chip to the at least some memory chips of the plurality of memory chips of second memory group.

In one example embodiment of inventive concepts, there is provided A semiconductor memory system comprising a memory module, the memory module including a printed circuit board, a first memory group and a second memory group on the printed circuit board, each of the first memory group and the second memory group comprising a plurality of memory chips, and buffer chip configured to output first clock signals to the first memory group and second clock signals to the second memory group. At least some distances that the first clock signals propagate from the buffer chip to at least some memory chips of the first memory group are identical to one another, and at least some distances that the second clock signals propagate from the buffer chip to at least some memory chips of the second memory group are identical to one another.

### BRIEF DESCRIPTION OF THE DRAWINGS

Example embodiments of inventive concepts will be more clearly understood from the following detailed description taken in conjunction with the accompanying drawings in which:

FIG. 1 is a schematic diagram showing a semiconductor memory system equipped with a memory module according to an example embodiment of inventive concepts;

FIG. 2A is a plan view showing a memory module according to an example embodiment of inventive concepts;

FIG. 2B is a plan magnified view of A of FIG. 2A, which shows a memory module according to an example embodiment of inventive concepts;

FIG. 3 is a timing diagram showing control signals and clock signals received by respective memory groups of a memory module according to an example embodiment of inventive concepts;

FIG. 4 is a plan view of a memory module according to an example embodiment of inventive concepts;

FIG. 5 is a cross-sectional view of a memory module according to an example embodiment of inventive concepts, taken along a second clock signal line of FIG. 4;

FIG. 6 is a plan view of a memory module according to an example embodiment of inventive concepts;

FIG. 7 is a cross-sectional view of a memory module according to an example embodiment of inventive concepts, taken along a second clock signal line of FIG. 6;

FIG. 8 is a graph for describing characteristics of a clock signal in a memory module according to an example embodiment of inventive concepts; and

FIG. 9 is a block diagram showing a computing system including a memory module according to an example embodiment of inventive concepts.

### DETAILED DESCRIPTION

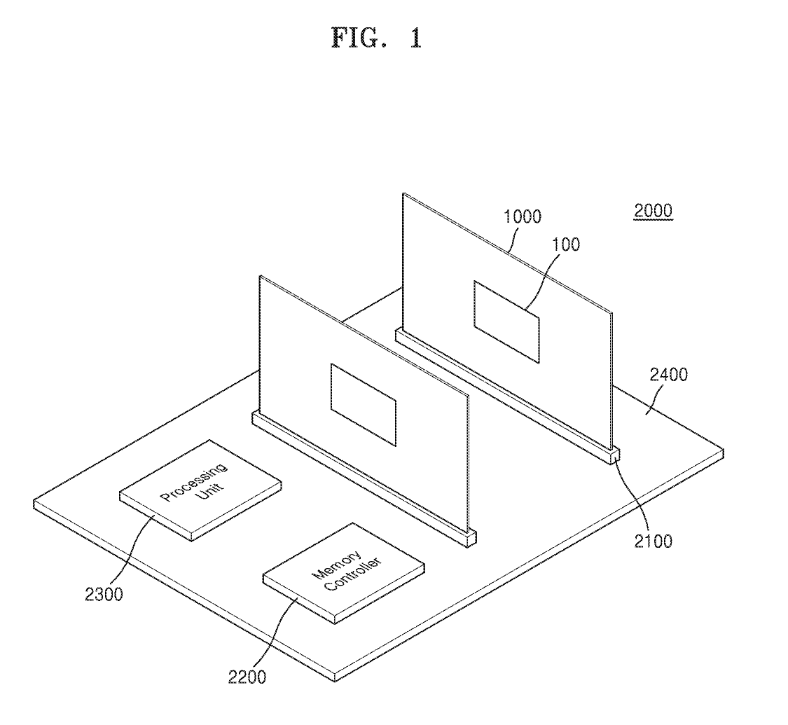

FIG. 1 is a schematic diagram showing a semiconductor memory system equipped with a memory module according to an example embodiment of inventive concepts.

Referring to FIG. 1, a semiconductor memory system 2000 may include a socket 2100, a memory controller 2200, a processing unit 2300, and a substrate 2400. The socket 2100, the memory controller 2200, and the processing unit 2300 may be attached to the substrate 2400 and electrically connected to one another through electric leads included in the substrate 2400. Furthermore, although FIG. 1 shows an example embodiment in which a memory module 1000 is mounted in the semiconductor memory system 2000, the memory module 1000 may be separated from the semiconductor memory system 2000. According to an example embodiment of inventive concepts, the semiconductor memory system 2000 may be or may include a mainboard or a computing system on which a memory module 1000 may be mounted, and the memory module 1000 may function as a data memory in the semiconductor memory system 2000.

The socket 2100 may be attached on the substrate 2400. The memory module 1000 may be mounted in the semiconductor memory system 2000 through the socket 2100, and may be electrically connected to other components of the semiconductor memory system 2000 through the socket 2100. For example, the memory module 1000 may be electrically connected to the memory controller 2200 through the socket 2100 and the substrate 2400. Although two sockets 2100 are shown in FIG. 1, inventive concepts are not limited thereto. The semiconductor memory system 2000 may include three or more sockets 2100, and thus the three or more memory modules 1000 may be mounted on the semiconductor memory system 2000.

According to an example embodiment of inventive concepts, the memory controller 2200 may output a control signal to the memory module 1000 to control the memory module 1000 mounted in the semiconductor memory system 2000 and may receive data from the memory module 1000. The processing unit 2300 may control the memory controller 2200 in order to write and/or read data to and/or from the memory module 1000. For example, the processing unit 2300 may transmit data to be written to the memory module 1000 to the memory controller 2200, and the memory controller 2200 may output an appropriate command signal to the memory module 1000 in order to write the data received from the processing unit 2300 to the memory module 1000.

The memory module 1000 may include a buffer chip 100 and a plurality of memory chips. The plurality of memory chips may be or may include dynamic random access memory (DRAM) chips including DRAM cells. Alternatively, the plurality of memory chips may include other memory cells that are randomly accessible, such as magnetic RAM (MRAM) cells, spin transfer torque magnetic RAM (STT-MRAM) cells, phase change RAM (PRAM) cells, and resistive RAM (RRAM) cells.

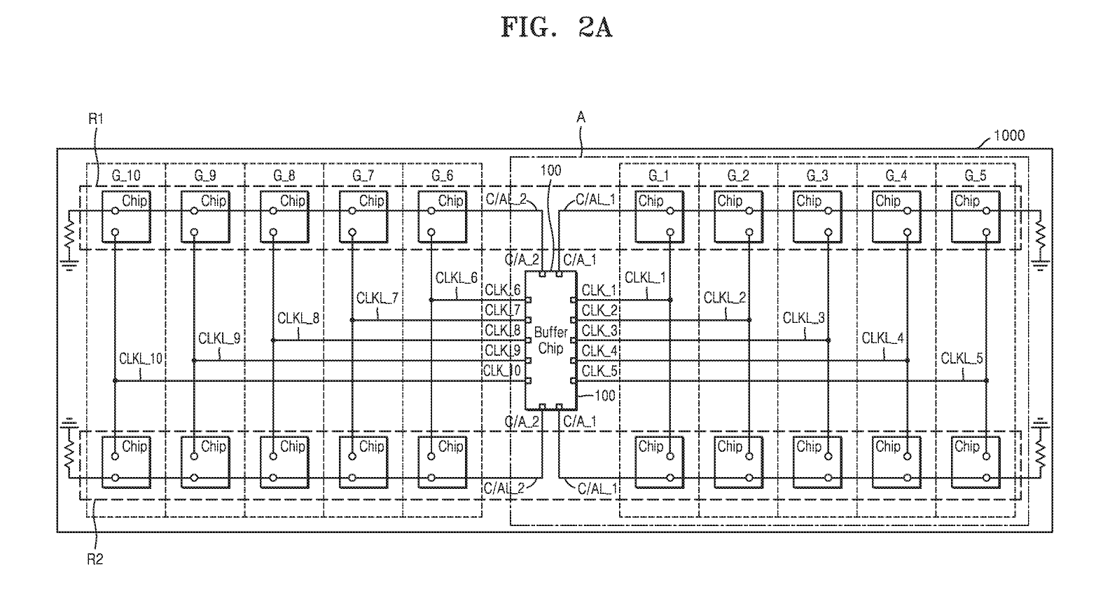

As described below with reference to FIGS. 2A, 2B, 4, and 6, the buffer chip 100 may receive a signal output from the memory controller 2200 and transmit the received signal to the plurality of memory chips included in the memory module 1000. According to an example embodiment of inventive concepts, the plurality of memory chips may be arranged in order to receive signals from the buffer chip 100 at precise, or specific, timings. For example, the plurality of memory chips may include at least one memory group including two or more memory chips, and two or more memory chips included in a same memory group may receive signals transmitted by the buffer chip 100 at a same timing. Therefore, a plurality of signal lines for signals output from the buffer chip 100 may be more easily routed in a limited space, and a load increase due to the plurality of memory chips connected to a signal line may be prevented or reduced.

FIG. 2A is a plan view of a memory module according to an example embodiment of inventive concepts. FIG. 2B is a plan magnified view of A of FIG. 2A, which shows a memory module according to an example embodiment of inventive concepts.

Referring to FIG. 2A, a memory module 1000 may include the buffer chip 100, first through fifth memory groups G_1 through G_5 shown on one side, or the right side of the buffer chip 100, and sixth through tenth memory groups G_6 through G_10 shown on another side, or the left side of the buffer chip 100. Although the first through fifth memory groups G_1 through G_5 and the sixth through tenth memory groups G_6 through G_10 are shown symmetrically around the buffer chip 100, inventive concepts is not limited thereto.

The buffer chip 100, the first through fifth memory groups G_1 through G_5 and the sixth through tenth memory groups G_6 through G_10 may be on a substrate, e.g., a printed circuit board (PCB). For example, as shown in FIG. 2A, the buffer chip 100 may be at the center portion of the PCB, and five memory groups may be on each side of the buffer chip 100. However, inventive concepts are not limited thereto, and the buffer chip 100 may be at an edge of the PCB. When the buffer chip 100 is at an edge of the PCB, only the first through fifth memory groups G_1 through G_5 may be on the PCB.

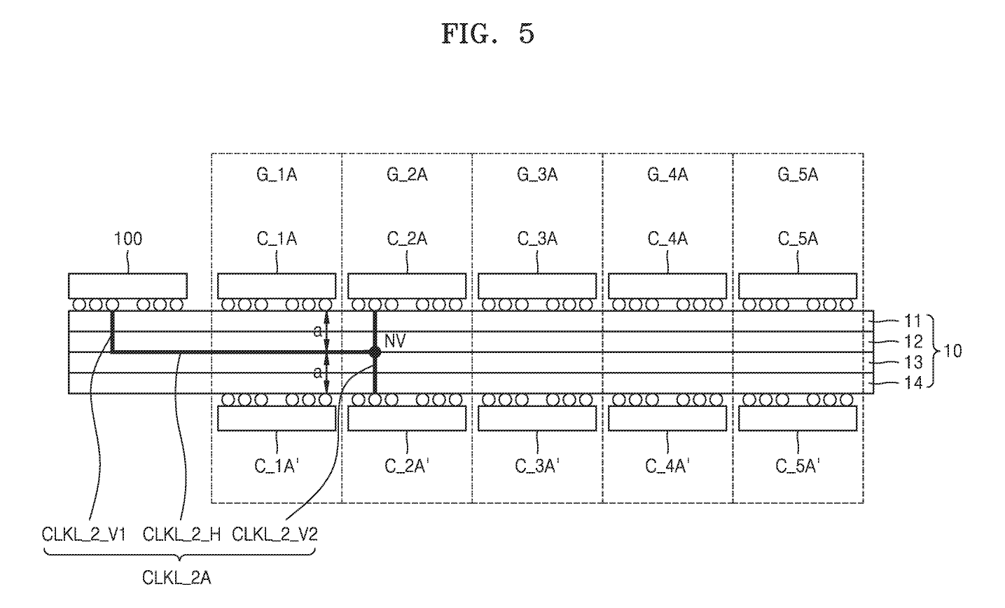

Each of, or at least some of, the first through fifth memory groups G_1 through G_5 and the sixth through tenth memory groups G_6 through G_10 may include a plurality of memory chips. For example, as shown in FIG. 2A, a plurality of memory chips included in the first through fifth memory groups G_1 through G_5 and the sixth through tenth memory groups G_6 through G_10 may be arranged in two rows total. However, although FIG. 2A shows that each of the first through tenth memory groups G_1 through G_10 includes two memory chips and the plurality of memory chips included in the first through tenth memory groups G_1 through G_10 are arranged in two rows, inventive concepts is not limited thereto, and the plurality of memory chips may also be arranged in three or more rows. An embodiment where the plurality of memory chips included in the first through fifth memory groups G_1 through G_5 and the sixth through tenth memory groups G_6 through G_10 are arranged in one row will be described below in detail with reference to FIG. 6.

The buffer chip 100 may buffer and forward a control signal and a clock signal received from a memory controller outside the memory module 1000. The buffer chip 100 may output a first control signal C/A_1 and first through fifth clock signals CLK_1 through CLK_5 to the plurality of memory chips included in the first through fifth memory groups G_1 through G_5. A second control signal C/A_2 and sixth through tenth clock signals CLK_6 through CLK_10 may be provided to the plurality of memory chips included in the sixth through tenth memory groups G_6 through G_10. The first control signal C/A_1 and the second control signal C/A_2 may include signals for controlling operations of the plurality of memory chips. For example, the first control signal C/A_1 and the second control signal C/A_2 may include command/address signals.

A first control signal line C/AL_1 may be connected to the buffer chip 100 and the first through fifth memory groups G_1 through G_5. The buffer chip 100 may output the first control signals C/A_1 to the first through fifth memory groups G_1 through G_5 through the first control signal line C/AL_1. Therefore, the first through fifth memory groups G_1 through G_5 may sequentially receive the first control signals C/A_1 transmitted through the first control signal line C/AL_1.

A second control signal line C/AL_2 may be connected to the buffer chip 100 and the sixth through tenth memory groups G_6 through G_10. The buffer chip 100 may output the second control signal C/A_2 to the sixth through tenth memory groups G_6 through G_10 through the second control signal line C/AL_2. Therefore, the sixth through tenth memory groups G_6 through G_10 may sequentially receive the second control signal C/A_2 transmitted through the second control signal line C/AL_2.

Since the first through fifth memory groups G_1 through G_5 and the sixth through tenth memory groups G_6 through G_10 are connected to different control signal lines, the first through fifth memory groups G_1 through G_5 and the sixth through tenth memory groups G_6 through G_10 may receive different command/address signals. For example, the first control signal C/A_1 and the second control signal C/A_2 may be identical to or different from each other. As shown in FIG. 2A, the first control signal line C/AL_1 and the second control signal C/AL_2 may include termination resistors in order to prevent or reduce distortions of the first control signal C/A_1 and the second control signal C/A_2 due to impedance mismatching, respectively. First through fifth clock signal lines CLKL_1 through CLKL_5 may transmit first through fifth clock signals CLK_1 through CLK_5 output from the buffer chip 100 to the first through fifth memory groups G_1 through G_5, respectively. Sixth through tenth clock signal lines CLKL_6 and CLKL_10 may transmit sixth through tenth clock signals CLK_6 and CLK_10 output from the buffer chip 100 to the sixth through tenth memory groups G_6 and G_10, respectively. The first through tenth clock signal lines CLKL_1 through CLKL_10 may be between a first row R1 and a second row R2.

Referring to FIGS. 2A and 2B, the first clock signal CLK_1 may be transmitted to the plurality of memory chips of the first memory group G_1 through the first clock signal line CLKL_1, where the first clock signal line CLKL_1 may be branched at a first node N1. Accordingly, distances that the first clock signals CLK_1 propagate from the buffer chip 100 to the respective plurality of memory chips included in the first memory group G_1 through the first clock signal line CLKL_1 may be substantially identical to one another and will be referred to as a first clock signal propagation distance L_1. For convenience of explanation, FIG. 2B shows that distances from the first node N1 to the plurality of memory chips included in the first memory group G_1 are different from one another. However, distances from the first node N1 to the plurality of memory chips included in the first memory group G_1 may be substantially identical to one another. Therefore, distances that the first clock signals CLK_1 propagate from the first node N1 to the plurality of memory chips included in the first memory group G_1I may be substantially identical to one another.

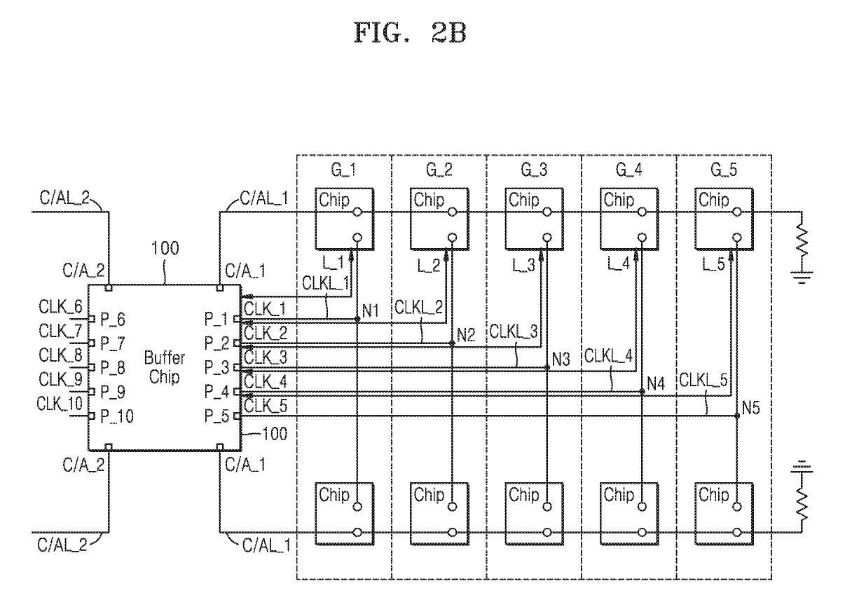

As described above regarding the first clock signal propagation distance L_1, distances that the second through fifth clock signals CLK_2 through CLK_5 propagate from the buffer chip 100 to the plurality of memory chips included in the second through fifth memory groups G_2 through G_5 through the second through fifth clock signal lines CLKL_2 through CLKL_5 are also identical to one another and will be referred to as second through fifth propagation distances L_2 through L_5, respectively. Therefore, each of, or at least some of, the first through fifth memory groups G_1 through G_5 may receive the same clock signals at a same timing. Timings of signals received by memory groups will be described below in detail with reference to FIG. 3.

The sixth through tenth memory groups G_6 through G_10 of FIG. 2A may be symmetrically arranged with respect to the first through fifth memory groups G_1 through G_5 of FIG. 2B around the buffer chip 100, where the descriptions of the first through fifth memory groups G_1 through G_5 may be equally applied to the sixth through tenth memory groups G_6 through G_10. The first through tenth clock signal lines CLKL_1 through CLKL_10 may be connected to different first through tenth pins P_1 to P_10 included in the buffer chip 100, respectively.

FIG. 3 is a timing diagram showing control signals and clock signals received by respective memory groups of a memory module according to an example embodiment of inventive concepts.

Referring to FIGS. 2B and 3, the first control signals C/A_1 may be provided to the first through fifth memory groups G_1 through G_5 through the first control signal line C/AL_1. Since distances from the buffer chip 100 to the first through fifth memory groups G_1 through G_5 are different from one another, distances that the first control signals C/A_1 propagate to the plurality of chips included in the first through fifth memory groups G_1 through G_5 through the first control signal line C/AL_1 may be different from one another. As a result, time points at which the first control signals C/A_1 arrive at the first through fifth memory groups G_1 through G_5 may be different from one another. As shown in FIG. 2B, since the first control signals C/A_1 output from the buffer chip 100 sequentially arrive at the first through fifth memory groups G_1 through G_5, the first control signals C/A_1 may arrive at the first through fifth memory groups G_1 through G_5 after first through fifth time delays D_1 through D_5 from the time point at which the first control signals C/A_1 are output from the buffer chip 100, respectively. Therefore, the delays of the first control signals C/A_1 may increase from the first memory group G_1 towards the fifth memory group G_5. For example, the first through fifth time delays D_1 through D_5 may increase in size from the first time delay D_1 towards the fifth time delay D_5.

The plurality of memory chips included in each the first through fifth memory groups G_1 through G_5 may be synchronized with rising edges of the first through fifth clock signals CLK_1 through CLK_5 received by the plurality of memory chips and latch the first control signals C/A_1. Therefore, timings at which the first through fifth clock signals CLK_1 through CLK_5 arrive at the first through fifth memory groups G_1 through G_5 may be determined based on the first through fifth time delays D_1 through D_5, and the first through fifth clock signal propagation distances L_1 through L_5 may also be determined based on the first through fifth time delay D_1 through D_5. Therefore, the buffer chip 100 may adjust timings for outputting the first through fifth clock signals CLK_1 through CLK_5 based on the first through fifth time delays D_1 through D_5 and the first through fifth clock signals propagation distances L_1 through L_5.

Accordingly, the memory module 1000 may include clock signal lines that are arranged, such that distances that clock signals transmitted from the buffer chip 100 propagate to respective groups of a plurality of memory chips included in the memory module 1000 are identical to one another. For example, memory groups may be classified based on distances from the buffer chip 100 to the plurality of memory chips of the respective memory groups, and the memory module 1000 may include clock signal lines that are arranged, such that distances that clock signals transmitted from the buffer chip 100 to the respective memory groups propagate are identical to one another.

The memory module 1000 according to an example embodiment of inventive concepts includes memory groups that are classified such that distances from the buffer chip 100 to respective memory chips or time delays of control signals transmitted from the buffer chip 100 are identical to one another. The memory module 1000 may include control signal lines connected to the respective memory groups. The buffer chip 100 may control the timings at which the buffer chip 100 output the clock signals and control signals so that the respective memory groups receive the same clock signals and same control signals. Therefore, a control signal line may be more easily routed in a limited space and the number of memory chips connected to one control signal line may be reduced.

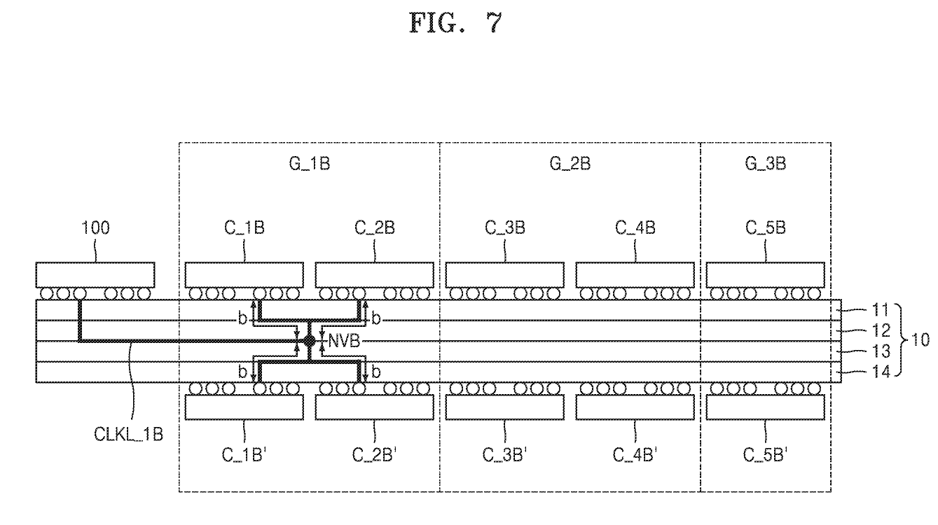

When or if the number of memory chips connected to one control signal line increases, the load of the control signal line increases. Therefore, a clock signal may be delayed and the integrity of the clock signal may not be ensured. As described above, the memory module 1000 according to an example embodiment of inventive concepts may help to ensure the integrity of a clock signal in a relative sense. Detailed descriptions thereof will be given below with reference to FIG. 8.

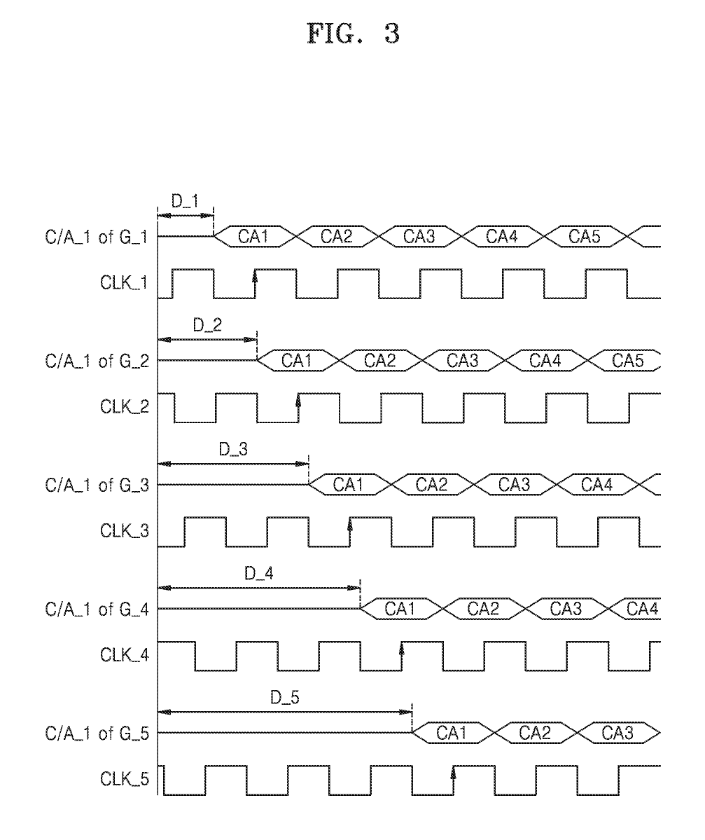

FIG. 4 is a plan view of a memory module according to an example embodiment of inventive concepts. Compared to the memory module 1000 of FIGS. 2A and 2B, a plurality of memory chips may be on the top and bottom surfaces of the PCB in a memory module 1000A of FIG. 4. In FIG. 4, the reference numerals identical to those in FIGS. 2A and 2B denote the same elements, and detailed descriptions of the components identical to those of FIGS. 2A and 2B will be omitted for simplicity of explanation.

Referring to FIG. 4, the memory module 1000A includes first through fifth memory groups G_1A through G_5A shown on one side, or the right side of the buffer chip 100 and sixth through tenth memory groups G_6A through G_10A shown on another side, or the left side of the buffer chip 100.

Each of, or at least some of, the first through fifth memory groups G_1A through G_5A and the sixth through tenth memory groups G_6A through G_10A may include a plurality of memory chips. The plurality of memory chips included in the first through fifth memory groups G_1A through G_5A and the sixth through tenth memory groups G_6A through G_10A may be arranged in two rows and arranged on the top and bottom surfaces of the PCB. Therefore, each memory group may include a total of four memory chips.

A first control signal line C/AL_1A may be connected to the buffer chip 100 and the first through fifth memory groups G_1A through G_5A. The buffer chip 100 may output the first control signals C/A_1 to the first through fifth memory groups G_1A through G_5A through the first control signal line C/AL_1A. Therefore, the first through fifth memory groups G_1A through G_5A may sequentially receive the first control signals C/A_1 transmitted through the first control signal line C/AL_1A.

First through fifth clock signal lines CLKL_1A through CLKL_5A may transmit the first through fifth clock signals CLK_1 through CLK_5 output from the buffer chip 100 to the first through fifth memory groups G_1A through G_5A, respectively. The distances that the first through fifth clock signals CLK_1 through CLK_5 propagate from the buffer chip 100 to the plurality of memory chips included in the first through fifth memory groups G_1A through G_5A may be substantially identical to one another for each memory group. Therefore, memory chips included in a same memory group may receive the same clock signals at a same time.

The distances that the first control signals C/A_1 propagate through the first control signal line C/AL_1A to the plurality of memory chips included in the first through fifth memory groups G_1A through G_5A may be different from one another, and thus time points at which the first control signals C/A_1 arrive at the first through fifth memory groups G_A through G_5A may be different from one another. Since the first control signals C/A_1 output from the buffer chip 100 sequentially arrive at the first through fifth memory groups G_1A through G_5A, the first control signals C/A_1 may arrive at first through fifth memory groups G_1A through G_5A after the first through fifth time delays from the time points at which the first control signals C/A_1 are output from the buffer chip 100, respectively. Based on the first through fifth time delays, respective timings at which the first through fifth clock signals CLK_1 through CLK_5 arrive at first through fifth memory groups G_1A through G_5A may be determined.

The respective distances that the first through fifth clock signals CLK_1 through CLK_5 propagate from the buffer chip 100 to the first through fifth memory groups G_1A through G_5A may be determined based on the first through fifth time delays. The buffer chip 100 may adjust timings for outputting the first through fifth clock signals CLK_1 through CLK_5 based on the first through fifth time delays and respective distances that the first through fifth clock signals CLK_1 through CLK_5 propagate from the buffer chip 100 to the first through fifth memory groups G_1A through G_5A.

The descriptions of the first through fifth memory groups G_1A through G_5A, the first control signal line C/AL_1A, and the first through fifth clock signal lines CLKL_1A through CLKL_5A are equally applicable to the sixth through tenth memory groups G_6A through G_10A, a second control signal line C/AL_2A, and sixth through tenth clock signal lines CLKL_6A through CLKL_10A.

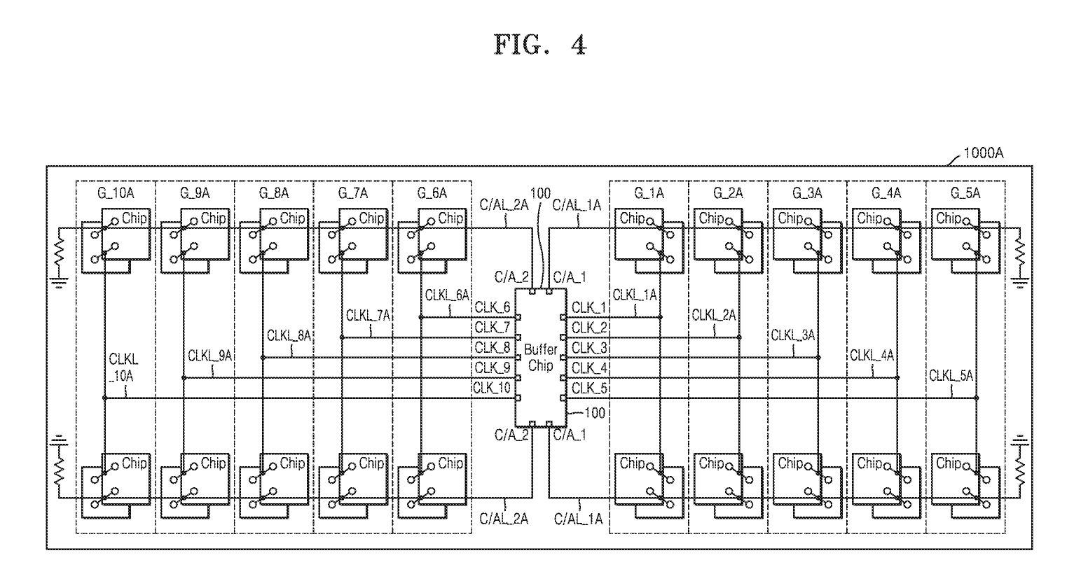

FIG. 5 is a cross-sectional view of a memory module according to an example embodiment of inventive concepts, taken along the second clock signal line CLKL_2A of FIG. 4.

Referring to FIGS. 4 and 5, a PCB 10 of a memory module 1000A may include a plurality of layers. For example, the PCB 10 may include first through fourth layers 11 through 14. A plurality of memory chips included in the first through fifth memory groups G_1A through G_5A may be mounted on the first layer 11, which is the topmost layer, or on the fourth layer 14, which is the bottommost layer. Therefore, some memory chips C_1A through C_5A of the first through fifth memory groups G_1A through G_5A may be mounted on the first layer 11 and some other memory chips C_1′A through C_5′A may be mounted on the fourth layer 14.

The second clock signal line CLKL_2A may transfer the second clock signal CLK_2 output from the buffer chip 100 to the memory chip C_2 and the memory chip C_2′ of the second memory group G_2A. Although FIG. 5 shows that a horizontal pattern CLKL_2_H of the second clock signal line CLKL_2A is in the third layer 13 to contact the second layer 12, inventive concepts is not limited thereto. In some embodiments, the horizontal pattern CLKL_2_H may be over a plurality of layers. As described above with reference to FIG. 3, the length of the second clock signal line CLKL_2A may vary according to the second time delay of the first control signal C/A_1 transmitted to the second memory group G_2A, and thus the shape of the pattern CLKL_2J may vary.

The second clock signal line CLKL_2A may include a first via structure CLKL_2_H_V1 and a second via structure CLKL_2_H_V2. The first via structure CLKL_2_H_V1 may interconnect the buffer chip 100 and the horizontal pattern CLKL_2_H, whereas the second via structure CLKL_2_H_V2 may interconnect the memory chip C_2A and the horizontal pattern CLKL_2_H. Therefore, the memory chip C_2A attached to the first layer 11 and the memory chip C_2′A attached to the fourth layer 14 may receive the second clock signals CLK_2 through the second via structure CLKL_2_H_V2.

A branching point NV may be formed at a point where the horizontal pattern CLKL_2_H and the second via structure CLKL_2_H_V2 meet each other. The length of the second via structure CLKL_2_H_V2 from the branching point NV to the memory chip C_2A and the length of the second via structure CLKL_2_H_V2 from the branching point NV to the memory chip C_2′ may both be a, thus being substantially identical to each other. Therefore, the memory chip C_2A and the memory chip C_2′ may receive the second clock signals CLK_2 transmitted from the buffer chip 100 at substantially same time points.

In the memory module 1000A according to an example embodiment of inventive concepts, a plurality of memory chips included in a same group may be controlled to receive the same clock signals. For example, memory groups may be classified based on distances from the buffer chip 100. In this embodiment, it is easy to implement clock signal lines connected to the memory chips included in each memory group to have substantially a same length, and the appropriate number of memory chips included in one group may be maintained. Therefore, the increase of the load of a clock signal line due to the increase of the number of memory chips connected to the clock signal line may be prevented or reduced, and thus the integrity of a clock signal may be ensured.

Although FIG. 5 shows only the second clock signal line (CLKL_2A), it will be understood that the first clock signal line CLKL_1A and the third through tenth clock signal lines CLKL_3A through CLKL_10A may also be similarly as the second clock signal line CLKL_2A.

FIG. 6 is a plan view of a memory module according to an example embodiment of inventive concepts. Compared to the memory module 1000 of FIGS. 2A and 2B, in a memory module 1000B of FIG. 6, a plurality of memory chips may be arranged in one row on each of the top and bottom surfaces of a PCB. In FIG. 6, the reference numerals identical to those in FIGS. 2A and 2B denote the same elements, and thus detailed descriptions of the components identical to those shown in FIGS. 2A and 2B will be omitted for simplicity of explanation.

Referring to FIG. 6, the memory module 1000B includes first through third memory groups G_1B through G_3B shown on the right side of the buffer chip 100 and fourth through sixth memory groups G_4B through G_6B shown on the left side of the buffer chip 100.

Each of, or at least some of, the first through third memory groups G_1B through G_3B and the fourth through sixth memory groups G_4B through G_6B may include a plurality of memory chips. The plurality of memory chips included in the first through third memory groups G_1B through G_3B and the fourth through sixth memory groups G_4B through G_6B may be arranged in one row and mounted on the topmost layer and the bottommost layer of the PCB. The number of memory chips included in each memory group may not be the same. For example, the first memory group G_1B, the second memory group G_2B, the fourth memory group G_4B, and the fifth memory group G_5B may include four memory chips each, whereas the third memory group G_3B and the sixth memory group G_6B may include two memory chips each. However, inventive concepts is not limited thereto, and the number of memory chips included in each memory group may be the same.

The first control signal line C/AL_1B may be connected to the buffer chip 100 and first through third memory groups G_1B through G_3B. The buffer chip 100 may output the first control signals C/A_1 to the first through third memory groups G_1B through G_3B through the first control signal line C/AL_1B. Therefore, the first through third memory groups G_1B through G_3B may sequentially receive the first control signals C/A_1 transmitted through the first control signal line C/AL_1B.

Distances that the first control signals C/A_1 propagate from the buffer chip 100 to the plurality of memory chips of the first memory group G_1B through the first control signal line C/AL_B may be identical to one another and will be referred to as a first distance. Furthermore, distances that the first control signals C/A_1 propagate from the buffer chip 100 to the plurality of memory chips of the second memory group G_2B through the first control signal line C/AL_B may be identical to one another and will be referred to as a second distance. Furthermore, distances that the first control signals C/A_1 propagate from the buffer chip 100 to the plurality of memory chips included in each of, or at least some of, the third through sixth memory groups G_3B through G_6B may also be substantially identical to one another.

The first through third clock signal lines CLKL_1B and CLKL_3B may transmit the first through third clock signals CLK_1 and CLK_3 output from the buffer chip 100 to the first through third memory groups G_1B and G_3B, respectively. Propagation distances of the first through third clock signals CLK_1 through CLK_3 from the buffer chip 100 to the plurality of memory chips included in each of, or at least some of, the first through third memory groups G_1B through G_3B may be substantially identical to one another for each of, or at least some of, the first through third memory groups G_1B through G_3B. Therefore, memory chips included in a same memory group may receive the same clock signals at a same time point.

Distances that the first control signals C/A_1 propagate to the plurality of memory chips included in each of the first through third memory groups G_1B through G_3B through the first control signal line C/AL_1B may be different from one another, and thus time points at which the first control signals C/A_1 arrive at the first through third memory groups G_1B through G_3B may be different from one another. The first control signals C/A_1 output from the buffer chip 100 may sequentially arrive at the first through third memory groups G_1B through G_3B after first through third time delays, respectively. Based on the first through third time delays, respective timings at which the first through third clock signals CLK_1 through CLK_3 arrive at the first through third memory groups G_1B through G_3B may be determined.

The distances that the first through third clock signal CLK_1 through CLK_3 propagate from the buffer chip 100 to the first through third memory groups G_1B through G_3B may be determined based on first through third time delays. The buffer chip 100 may adjust timings for outputting the first through third clock signals CLK_1 through CLK_3 based on the first through third time delays and the distances that the first through third clock signals CLK_1 through CLK_3 propagate from the buffer chip 100 to the first through third memory groups G_1B through G_3B.

The descriptions of the first through third memory groups G_1B through G_3B, the first control signal line C/AL_1B, and the first through third clock signal lines CLKL_1B through CLKL_3B are equally applicable to fourth through sixth memory groups G_4B through G_6B, a second control signal line C/AL_2B, and fourth through sixth clock signal lines CLKL_4B through CLKL_6B.

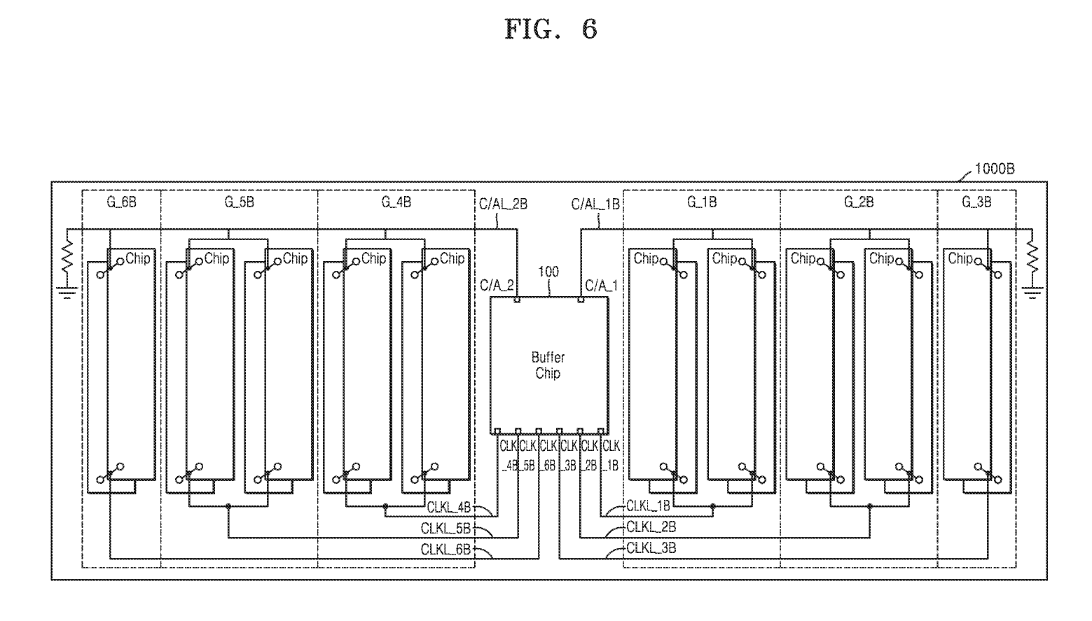

FIG. 7 is a cross-sectional view of a memory module according to an example embodiment of inventive concepts, taken along the second clock signal line CLKL_1B of FIG. 6. In FIG. 7, the reference numerals identical to those in FIG. 5 denote the same elements, and thus detailed descriptions of the components identical to those shown in FIG. 5 will be omitted for simplicity of explanation.

Referring to FIGS. 6 and 7, the PCB 10 of a memory module 1000B may include a plurality of layers, and a plurality of memory chips included in the first through third memory groups G_1B through G_3B may be mounted on the first layer 11, which is the topmost layer, or on the fourth layer 14, which is the bottommost layer. Some memory chips C_1B through C_5B included in the first through third memory groups G_1B through G_3B may be mounted on the first layer 11 and some other memory chips C_B′ through C_5B′ may be mounted on the fourth layer 14. The first memory group G_1B may include a plurality of memory chips C_1B, C_2B, C_1B′, and C_2B′, the second memory group G_2B may include a plurality of memory chips C_3B, C_4B, C_3B′, and C_4B′, and the third memory group G_3B may include a plurality of memory chips C_5B and C_5B′.

The first clock signal line CLKL_1B may transmit the first clock signal CLK_1 output from the buffer chip 100 to the plurality of memory chips C_1B, C_2B, C_1B′, and C_2B′ of the first memory group G_1B. Like the second clock signal line CLKL_2A of FIG. 5, the first clock signal line CLKL_1B may include a horizontal pattern horizontally formed on the same layer of the PCB 10 and a via structure to penetrate through at least one layer. The length of the first clock signal line CLKL_1B may vary according to the first time delay of the first control signal C/A_1 transmitted to the first memory group G_1B.

The first clock signal line CLKL_1B may be branched at a branching point NVB and connected to a plurality of memory chips C_1B, C_2B, C_1B′, and C_2B′ of the first memory group G_1B, respectively. The length of the first clock signal line CLKL_1B from the branching point NVB to the memory chip C_1B, the length of the first clock signal line CLKL_1B from the branching point NVB to the memory chip C_2B, the length of the first clock signal line CLKL_B from the branching point NVB to the memory chip C_1B′, and the length of the first clock signal line CLKL_1B from the branching point NVB to the memory chip C_2B′ may all be b, thus being substantially identical to one another. Therefore, the plurality of memory chips C_1B, C_2B, C_1B′, and C_2B′ of the first memory group G_1B may receive the first clock signals CLK_1 transmitted from the buffer chip 100 at substantially same time points.

In the memory module 1000B according to an example embodiment of inventive concepts, a plurality of memory chips included in a same group may be controlled to receive the same clock signals. For example, memory chips corresponding to a same time delays based on time elapsed for control signals to propagate from the buffer chip 100 to the memory chips may constitute one group. Since a clock signal line is for each group, the clock signal line may be more easily routed. When a plurality of memory chips are managed as a group and clock signals are transmitted thereto, the number of memory chips connected to one clock signal line may be limited to the number of memory chips included in the group. Therefore, as described below with reference to FIG. 8, the increase of the load of one clock signal line due to the increase of the number of memory chips connected to the clock signal line may be prevented or reduced, and thus the integrity of clock signals may be ensured.

Although FIG. 7 shows only the first clock signal line CLKL_1B, it will be understood that the second through sixth clock signal lines CLKL_2B through CLKL_6B may be also be similarly as the first clock signal line CLKL_1B.

FIG. 8 is a graph for describing characteristics of a clock signal in a memory module according to an example embodiment of inventive concepts. Specifically, the graph of FIG. 8 shows a voltage change of a clock signal according to a frequency change.

Referring to FIGS. 4 and 8, the example embodiment of FIG. 8 relates to the memory module 1000A of FIG. 4. Compared with the memory module 1000A according to the example embodiment of inventive concepts shown in FIG, a comparative example relates to a memory module in which a plurality of memory chips are not classified into a group, a plurality of memory chips included in a first row together with one clock signal line are connected to the clock signal line, and a plurality of memory chips included in a second row are connected to another clock signal line.

In both the comparative example and the present example embodiment, as the frequency of a clock signal increases, the voltages of signals transmitted from the buffer chip 100 to the plurality of memory chips decrease. However, as compared with the present example embodiment, the voltages of signals decrease sharply as the frequency of a clock signal increases. Since a memory module is desirable to transmit a high-frequency signal in order to operate at a high speed, it is clear that the integrity of clock signal transmitted during a high-speed operation is not ensured in the comparative example. On the contrary, in the present example embodiment, since high-frequency clock signals may be transmitted while maintaining a constant voltage, a memory module according to the present example embodiment may be used even during a high-speed operation.

In the comparative example, five memory chips are connected to one clock signal line. Since each memory chip becomes a load to the clock signal line, it may become more and more difficult to transmit a clock signal as the number of memory chips connected to the clock signal line increases. On the contrary, in the present example embodiment, since four memory chips are connected to one clock signal line, loads to the clock signal line are relatively small as compared with the comparative example, and thus the integrity of clock signals may be ensured. This may also be applied to the memory modules 1000 and 1000B of FIGS. 2A and 6B.

Therefore, since the memory modules 1000, 1000A, and 1000B according to example embodiments of inventive concepts classify a plurality of memory chips into a group, clock signal lines may be more easily routed and the integrity of clock signals may be ensured.

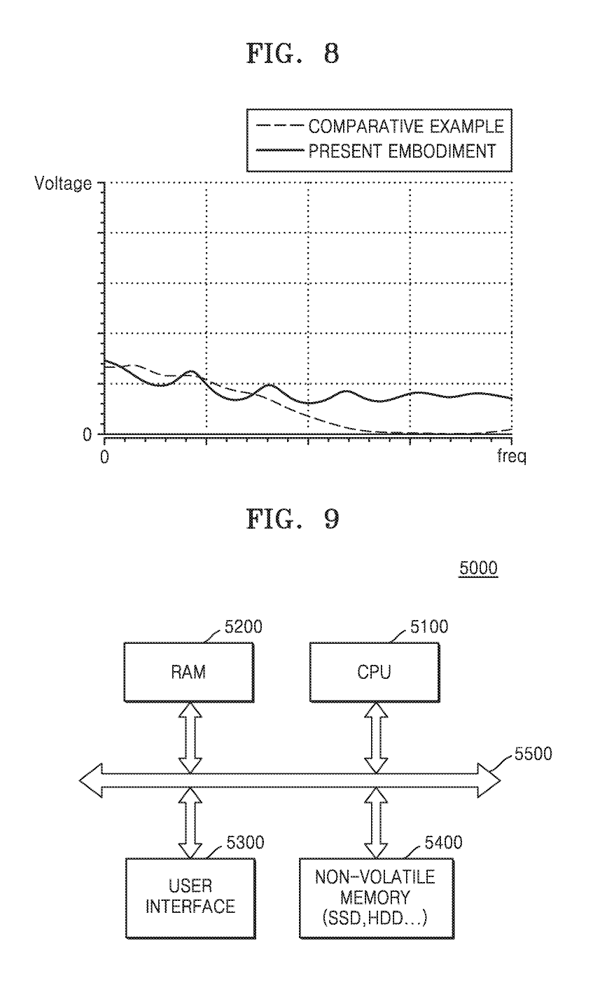

FIG. 9 is a block diagram showing a computing system including a memory module according to an example embodiment of inventive concepts.

Referring to FIG. 9, a computing system 5000 includes a central processing unit (CPU) 5100, a RAM 5200, a user interface 5300, and a non-volatile memory 5400. The components may be electrically connected to a bus 5500 and communicate with one another through the bus 5500.

In the computing system 5000, a memory module according to an example embodiment of inventive concepts may be mounted as the RAM 5200. The memory module mounted as the RAM 5200 may be or may include one of the memory modules 1000, 1000A, and 1000B described above with reference to FIGS. 2A, 4, and 6. For example, as in the previous example embodiments described above, the memory module mounted as the RAM 5200 may include a memory group including a plurality of (two or more) memory chips, and the plurality of memory chips and signal lines may be arranged, such that a plurality of memory chips included in a same memory group receive signals at a same timing.

The CPU 5100 may perform certain calculations or tasks. The CPU 5100 may communicate with the user interface 5300 and the non-volatile memory 5400 through the bus 5500.

The user interface 5300 may include an input unit, e.g., a keyboard, a keypad, a mouse, etc., for receiving an input signal from a user and a output unit, e.g., a printer, a display device, etc., for providing an output signal to a user.

The non-volatile memory 540 may include a non-volatile memory, such as an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), and a ferroelectric random access memory (FRAM), or a magnetic disk, for example.

The computing system 5000 may further include ports capable of communicating with a video card, a sound card, a memory card, a USB device, or other electronic devices. The computing system 5000 may be implemented as a personal computer or a portable electronic device, such as a laptop computer, a mobile phone, a personal digital assistant (PDA), and a camera.

While inventive concepts has been particularly shown and described with reference to example embodiments thereof, it will be understood that various changes in form and details may be made therein without departing from the spirit and scope of the following claims.

What is claimed is:

1. A memory module comprising:
a first memory group and a second memory group, each comprising a plurality of memory chips;
a buffer chip configured to output a control signal, first clock signals, and second clock signals;
a control signal line connected to the buffer chip, at least some memory chips of the plurality of chips of the first memory group, and at least some memory chips of the plurality of chips of the second memory group;
a first clock signal line through which the first clock signals are configured to propagate from the buffer chip to the at least some memory chips of the plurality of memory chips of the first memory group;
a second clock signal line through which second clock signals are configured to propagate from the buffer chip to the at least some memory chips of the plurality of memory chips of the second memory group; and wherein
at least some distances that the first clock signals propagate from the buffer chip to the at least some memory chips of the plurality of memory chips of the first memory group through the first clock signal line are identical to one another, and
at least some distances that the second clock signals propagate from the buffer chip to the at least some memory chips of the plurality of memory chips of the second memory group through the second clock signal line are identical to one another.

2. The memory module of claim 1, wherein
the control signal includes command/address signals, and
the control signal line is configured to transfer the command/address signals to the first memory group and the second memory group.

3. The memory module of claim 2, wherein, from the buffer chip, the command/address signals are configured to arrive at the at least some memory chips of the plurality of memory chips of the first memory group after a first time delay and are configured to arrive at the at least some memory chips of the plurality of memory chips of the second memory group after a second time delay.

4. The memory module of claim 3, wherein the first time delay indicates a first distance from the buffer chip to the at least some memory chips of the plurality of memory chips of the first memory group, and the second time delay indicates a second distance from the buffer chip to the at least some memory chips of the plurality of memory chips of the second memory group.

5. The memory module of claim 3, wherein the buffer chip is configured to adjust timings for outputting the first clock signals and the second clock signals based on the first time delay, the second time delay, the first distance, and the second distance.

6. The memory module of claim 1, wherein
the first memory group, the second memory group, and the buffer chip are on a printed circuit board (PCB), the PCB including a plurality of layers,
the at least some memory chips of the plurality of memory chips of the first memory group are on a first surface of the PCB,
at least some other memory chips of the plurality of memory chips of the first memory group are on a second surface of the PCB opposite to the first surface,
the at least some memory chips of the plurality of memory chips of the second memory group are on the first surface of the PCB,
at least some other memory chips of the plurality of memory chips of the second memory group are on the second surface of the PCB,
the at least some memory chips of the plurality of memory chips of the first memory group on the first surface are connected to the at least some other memory chips of the plurality of memory chips of the first memory group through at least one via structure, and
the at least some memory chips of the plurality of memory chips of the second memory group on the first surface are connected to the at least some other memory chips of the plurality of memory chips of the second memory group through at least one other via structure.

7. The memory module of claim 1, wherein the first memory group and the second memory group are on one side with respect to the buffer chip.

8. The memory module of claim 1, wherein
the at least some memory chips of the plurality of memory chips of the first memory group are arranged in a first row, and the at least some memory chips of the plurality of memory chips of the second memory group are arranged in a second row, and
the first clock signal line and the second clock signal line are arranged between the first row and the second row.

9. The memory module of claim 1, wherein the buffer chip includes a first pin connected to the first clock signal line, and a second pin connected to the second clock signal line.

10. A memory module comprising:
a first memory group and a second memory group, each comprising a plurality of memory chips;
a buffer chip configured to output control signals, first clock signals, and second clock signals;
a first control signal line connected to the buffer chip, at least some memory chips of the plurality of memory chips of the first memory group, and at least some memory chips of the plurality of memory chips of the second memory group, and the first control signal line configured to transmit the control signals from the buffer chip to the first and second memory groups;
a first clock signal line configured to transmit the first clock signals to the plurality of memory chips of the first memory group; and
a second clock signal line configured to transmit the second clock signals to the plurality of memory chips of the second memory group,
wherein distances from the buffer chip to the at least some memory chips of the plurality of memory chips of the first memory group is different from distances from the buffer chip to the at least some memory chips of the plurality of memory chips of the second memory group.

11. The memory module of claim 10, wherein
the buffer chip is at a center portion of a printed circuit board (PCB), and
the first memory group and the second memory group are on one side with respect to the buffer chip.

12. The memory module of claim 11, further comprising:
a third memory group and a fourth memory group, each comprising a plurality of memory chips;
a second control signal line connected to the buffer chip, the third memory group, and
the fourth memory group;
a third clock signal line configured to transmit third clock signals to the plurality of memory chips of the third memory group; and
a fourth clock signal line configured to transmit fourth clock signals to the plurality of memory chips of the fourth memory group,
wherein the buffer chip is configured to output the third clock signals and the fourth clock signals.

13. The memory module of claim 12, wherein the buffer chip is between the first memory group and the third memory group, and the buffer chip is between the second memory group and the fourth memory group.

14. The memory module of claim 10, wherein
the control signals comprise command/address signals,
the first control signal line is configured to transfer the command/address signals to the first memory group and the second memory group,
distances that the control signals propagate from the buffer chip to the plurality of memory chips of the first memory group through the first control signal line are identical to one another, and
distances that the control signals propagate from the buffer chip to the plurality of memory chips of the second memory group through the first control signal line are identical to one another.

15. The memory module of claim 10, wherein the first memory group and the second memory group include a same number of memory chips.

16. The memory module of claim 10, wherein
the control signals comprise command/address signals,
the first control signal line is configured to transfer the command/address signals to the first memory group and the second memory group,
distances that the first clock signals propagate from the buffer chip to the plurality of memory chips of the first memory group through the first clock signal line are identical to one another, and
distances that the control signals propagate from the buffer chip to the plurality of memory chips of the second memory group through the second clock signal line are identical to one another.

17. A semiconductor memory system comprising:
a memory module, the memory module including,
a printed circuit board,
a first memory group and a second memory group on the printed circuit board, each of the first memory group and the second memory group comprising a plurality of memory chips, and
a buffer chip configured to output first clock signals to the first memory group and second clock signals to the second memory group, wherein
at least some distances that the first clock signals propagate from the buffer chip to at least some memory chips of the first memory group are identical to one another, and
at least some distances that the second clock signals propagate from the buffer chip to at least some memory chips of the second memory group are identical to one another.

18. The semiconductor memory system of claim 17, further comprising:
a substrate; and
a socket attached on the substrate, the socket being configured to mount the memory module on the substrate.

19. The semiconductor memory system of claim 18, further comprising:
a processing unit mounted on the substrate; and
a memory controller mounted on the substrate.

20. The semiconductor memory system of claim 19, wherein
the memory controller is configured to output a control signal to the memory module to control the memory module, and
the processing unit is configured to control the memory controller to at least one of write data to the memory module and read data from the memory module.
